(19) United States
(12) Patent Application Publication
(10) Pub. No.: US 2009/0166774 A1
(43) Pub. Date: Jul. 2, 2009

(54) WIRE BONDING METHOD AND SEMICONDUCTOR DEVICE

(75) Inventor: Hidenobu TAKAHIRA, Kurokawa-gun (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM Corporation, Tokyo (JP)

(21) Appl. No.: 12/343,332

(22) Filed: Dec. 23, 2008

(30) Foreign Application Priority Data
Dec. 27, 2007 (JP) 2007-335773

(51) Int. Cl. H01L 31/02; H01L 21/60; H01L 23/498

(52) U.S. Cl. 257/431; 438/106; 257/737; 257/E21.506; 257/E23.068; 257/E31.11

(57) ABSTRACT

First and second semiconductor chips are arranged side by side on a package base. A plurality of electrode pads with exposed Al films are formed at regular intervals on the first and second semiconductor chips. An Au bump is formed on each electrode pad of the second semiconductor chip. Each electrode pad of the first semiconductor chip is paired with each electrode pad of the second semiconductor chip. The electrode pads of each pair are equally spaced, and interconnected with a gold wire by wire bonding. In the wire bonding process, ball bonding is performed to the electrode pad of the first semiconductor chip as a first target, and stitch bonding is performed to the Au bump on the electrode pad of the second semiconductor chip as a second target.

### FIELD OF THE INVENTION

The present invention relates to wire bonding methods and semiconductor devices, and more particularly to a wire bonding method for connecting a plurality of semiconductor chips, and a multi-chip package type semiconductor device which encapsulates semiconductor chips connected to each other by this wire bonding method.

### BACKGROUND OF THE INVENTION

Many of current semiconductor devices incorporate a plurality of functionally-different integrated circuits (such as, a memory circuit and a logic circuit) on a single tip (monolithically) to achieve downsizing, low cost, low power consumption, and high operation speed. There remain, however, various technical difficulties in this single chip scheme especially in the event of incorporating the integrated circuits of low manufacturing compatibility, such as an analog circuit that handles small amplitude signals and a digital circuit that handles two kinds of signals with large amplitude differences, or the circuits that require different process rules according to their tolerance and power supply voltages. To incorporate such low-compatible circuits, separate semiconductor chips are first manufactured and attached on a single board, and then connected to each other (see, for example, Japanese Laid-open Publication No. 2000-236061).

In a chip package (multi-chip package), semiconductor chips are arranged side by side and encapsulated. Alternatively, semiconductor chips are stacked above and below, and this configuration is called a stacked package (see, for example, U.S. Pat. No. 6,836,002). In either configuration, the semiconductor chips are electrically interconnected by a wire bonding method.

In the wire bonding method, a wire (thin metallic wire) is first inserted through a capillary, and a tip of the wire is melted into a ball by discharge heating. The ball of the wire is then pressed onto a first target, and bonded thereto (a step called first bonding or ball bonding) using an ultrasonic welding method (a bonding method using the action of heat and ultrasonic energy). Subsequently, the capillary is moved to pull out the wire, which is then pressed onto a second target and joined thereto (a step called second bonding or stitch bonding) by the ultrasonic welding method.

Generally, in the wire bonding method, the wire is made of gold (Au), the first target is an electrode pad of a semiconductor chip, and the second target is an inner lead formed in a package substrate. In most cases, the electrode pad as the first target consists of a thin metallic film composed mostly of aluminum (Al) which is different from the material of the wire. However, during the ball bonding, the ball and the electrode pad creates Au—Al alloy at their joint, and this Au—Al alloy provides adequate bond strength. On the other hand, the stitch bonding is performed without making a ball, and the wire is pressed weakly. However, the inner lead as the second target is generally plated with gold, which is the same material as the wire, and metal-to-metal joint of the same material (Au—Au) provides adequate bond strength.

The stacked package disclosed in the U.S. Pat. No. 6,836,002, however, requires wire bonding to interconnect the electrode pads of the separate semiconductor chips. In this case, the first and the second targets are both electrode pads made of different material from the wire. It is therefore difficult to obtain adequate bond strength by the stitch bonding, which may result in bond failure.

Further, in the event of connecting electrode pads of two semiconductor chips, if the wires have different lengths, potential difference and timing difference may be caused between the signals on the wires.

### SUMMARY OF THE INVENTION

In view of the foregoing, a primary object of the present invention is to provide a wire bonding method to prevent poor joint between electrode pads.

Another object of the present invention is to provide a semiconductor device configured to reduce variation in signals transmitted between electrode pads of two semiconductor chips that are interconnected by the wire bonding method.

In order to achieve the above and other objects, a wire bonding method according to the present invention includes an arrangement step, a first bonding step and a second bonding step. In the arrangement step, first and second semiconductor chips are arranged such that an array of first electrode pads of the first semiconductor chip lies next to an array of second electrode pads of the second semiconductor chip. A gold bump is formed on each of the second electrode pads of the second electrode pad array. In the first bonding step, one end of a gold wire is bonded by ball bonding to one of the first electrode pads. In the second bonding step, the other end of the gold wire is bonded by stitch bonding to the gold bump on a corresponding one of the second electrode pads.

It is preferred to form the other end of the gold wire by firstly bonding the gold wire in the middle to the gold bump and severing the gold wire.

It is also preferred that the first and second semiconductor chips are arranged side by side, or stacked above and below, and fixed on a package base. The first and second electrode pad arrays are arranged parallel to each other.

A semiconductor device according to the present invention has first and second semiconductor chips arranged side by side or stacked above and below on a package base. On the first semiconductor chip is formed a first electrode pad array having a plurality of first electrode pads which are arranged at regular intervals. On the second semiconductor chip is formed a second electrode pad array having a plurality of second electrode pads arranged at regular intervals so as to correspond to the first electrode pad array. The first and second electrode pad arrays are arranged parallel to each other. On each of the second electrode pads, a gold bump is formed. One of the first electrode pad and a corresponding one of the second electrode pads are interconnected with a gold wire. One end of the gold wire is bonded to the first electrode pad by ball bonding. The other end of the gold wire is bonded to the gold bump on the second electrode pad by stitch bonding.

In a preferred embodiment of the present invention, the first semiconductor chip is a solid-state image sensor having photoelectric-conversion elements, vertical transfer paths and output amplifiers. The photoelectric-conversion elements are arranged in two-dimensional matrix. The vertical transfer paths are provided alongside of each line of the photoelectric-conversion elements. The output amplifiers are provided at a terminal of each vertical transfer path so as to convert signal charges from the vertical transfer path into voltage signals. Each of the output amplifiers is connected to a corresponding one of the first electrode pads.

Additionally, the second semiconductor chip includes a selector and an A/D converter. The selector selects one of the second electrode pads. The A/D converter converts the voltage signal from the second electrode pad, selected by the selector, into a digital signal.

Also, the package base has an open topped box shape, and a transparent plate is fixed onto this package base.

According to the wire bonding method of the present invention, it is possible to prevent poor joint of the electrode pads. According to the semiconductor device of the present invention, since the electrode pads of the first and second semiconductor chips are arranged at the same regular intervals, it is possible to reduce variation in the signals transmitted between the electrode pads interconnected by the wire bonding method.

### BRIEF DESCRIPTION OF THE DRAWINGS

The above objects and advantages of the present invention will become more apparent from the following detailed description when read in connection with the accompanying drawings, in which:

FIG. 1 is a plan view of a semiconductor device according to a first embodiment of the present invention;

FIG. 2 is a cross-sectional view along II-II line of FIG. 1;

FIG. 3 is an enlarged cross-sectional view around a pair of electrode pads interconnected by wire bonding;

FIG. 4 is a schematic diagram of first and second semiconductor chips;

FIG. 5 is a flowchart for a manufacturing process of the semiconductor device;

FIG. 6A and FIG. 6B are explanatory views illustrating a first bonding step to a first electrode pad;

FIG. 7A and FIG. 7B are explanatory views illustrating a second bonding step to a second electrode pad;

FIG. 8 is a plan view of a semiconductor device according to a second embodiment of the present invention; and

FIG. 9 is a cross-sectional view along IX-IX line of FIG. 8.

### DETAILED DESCRIPTION OF THE PREFERRED EMBODIMENTS

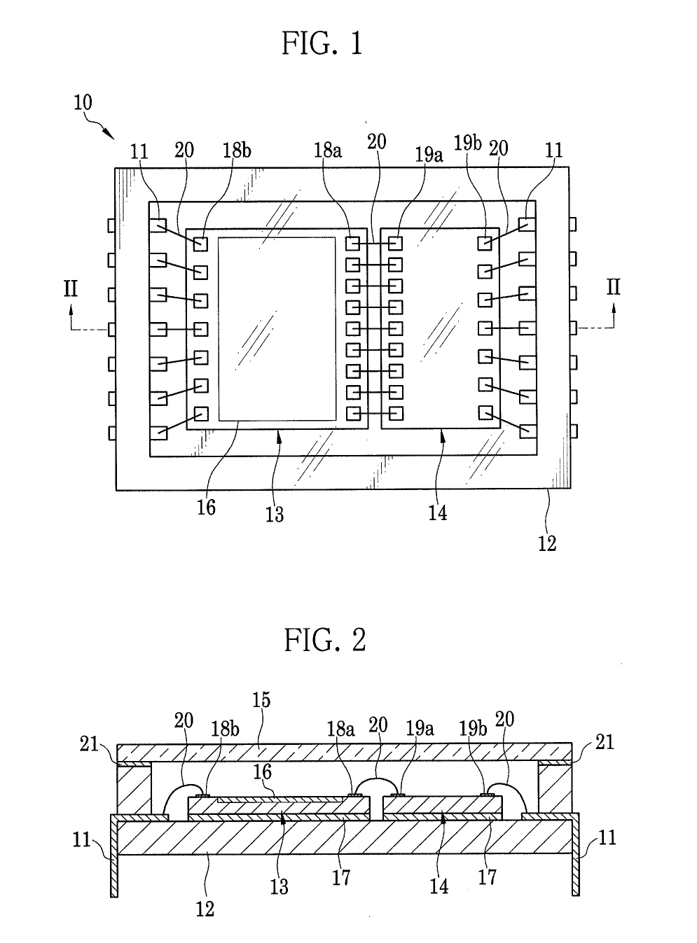

Referring to FIG. 1 and FIG. 2, a semiconductor device 10 includes a package base 12 having a plurality of lead terminals 11, first and second semiconductor chips 13, 14 fixed on the package base 12, and a transparent plate such as a cover glass 15 to cover an opening in an upper portion of the package base 12.

The package base 12 is an open-topped, box-shaped container made of, for example, ceramic. The lead terminals 11 having an L-shaped cross section penetrate side walls of the package base 12, and are partially exposed outward. These lead terminals 11 are plated with gold.

The first semiconductor chip 13 is a CCD (Charge Coupled Device) type solid-state image sensor having a light receiving area 16 on the top surface. The second semiconductor chip 14 is a peripheral circuit element including an A/D conversion circuit for converting analog image signals from the first semiconductor chip 13 into digital signals. The first and second semiconductor chips 13, 14 are fixed side by side on a bottom plate of the package base 12 by adhesive layers 17.

On the top surface of the first semiconductor chip 13, a plurality of electrode pads 18a, 18b are arranged at regular intervals to form electrode pad arrays along two opposite sides of the chip. Similarly, on the top surface of the second semiconductor chip 14, a plurality of electrode pads 19a, 19b are arranged at regular intervals to form electrode pad arrays along two opposite sides of the chip 14 respectively.

The electrode pads 18a of the first semiconductor chip 13 are output terminals to send out image signals. Each of the electrode pads 18a is connected through a wire 20 to a corresponding one of the electrode pads 19a. The electrode pads 18a, 19a are arranged at the same regular intervals (not more than 100 μm), such that each electrode pad 18a pairs with the corresponding electrode pad 19a. Additionally, the electrode pads 18a, 19a of each pair are equally spaced, and the wires 20 connecting the electrode pads 18a and 19a have substantially the same length.

The electrode pads 18b of the first semiconductor chip 13 are input terminals to receive power supply voltages and drive signals. Each of the electrode pads 18b is connected through wire 20 to one of the lead terminals 11. The electrode pads 19b of the second semiconductor chip 14 are output terminals to send out digital image signals or input terminals to receive power supply voltages. Each of the electrode pads 19b is connected through the wire 20 to one of the lead terminals 11 on the other side of the package base 12. The interval between the lead terminals 11 is 300 μm larger than the interval between the electrode pads 18b or 19b.

The cover glass 15 is fixed by an adhesive layer 21 provided on the top surfaces of the side walls of the package base 12. Together with the package base 12, the cover glass 15 encapsulates the first and second semiconductor chips 13, 14 air-tightly.

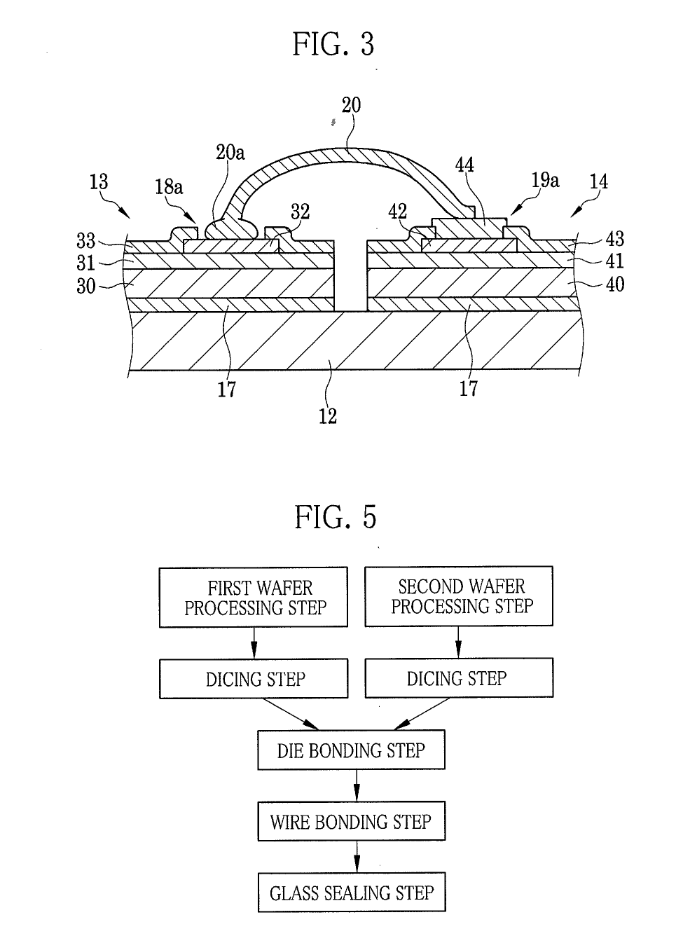

As shown in FIG. 3, the first semiconductor chip 13 has a silicon substrate 30. In electrode pad-forming regions on this silicon substrate 30, there is provided an interlayer film 31 composed of a stack of a silicon dioxide film, a barrier metal and the like. Formed on the interlayer film 31 are an Al film 32 that composes the electrode pad 18a, and a surface protection film 33 that covers the margin of the Al film 32. Similarly, the second semiconductor chip 14 has a silicon substrate 40. In electrode pad-forming regions on this silicon substrate 40, there is provided an interlayer film 41 composed of a stack of a silicon dioxide film, a barrier metal and the like. Formed on the interlayer film 31 are an Al film 42 that composes the electrode pad 19a, and a surface protection film 43 that covers the margin of the Al film 42. The Al films 32, 42 are a thin metallic film composed mostly of aluminum.

The wire 20 is a thin line of gold (Au). One end of the wire 20 is connected to the electrode pad 18a by ball bonding, and the other end of thereof is connected to the electrode pad 19a by stitch bonding. Namely, a ball 20a is formed at a tip of the wire 20 and pressed onto the electrode pad 18a to create Au—Al alloy at this point of contact, so that one end of the wire 20 is bonded to the electrode pad 18a. On the other hand, formed by plating on the electrode pad 19a is a gold (Au) bump 44 to which the other end of the wire 20 is pressed and joined. Since the Au bump 44 and the wire 20 are securely joined by Au—Au bond, the bond strength between the wire 20 and the electrode pad 19a is increased.

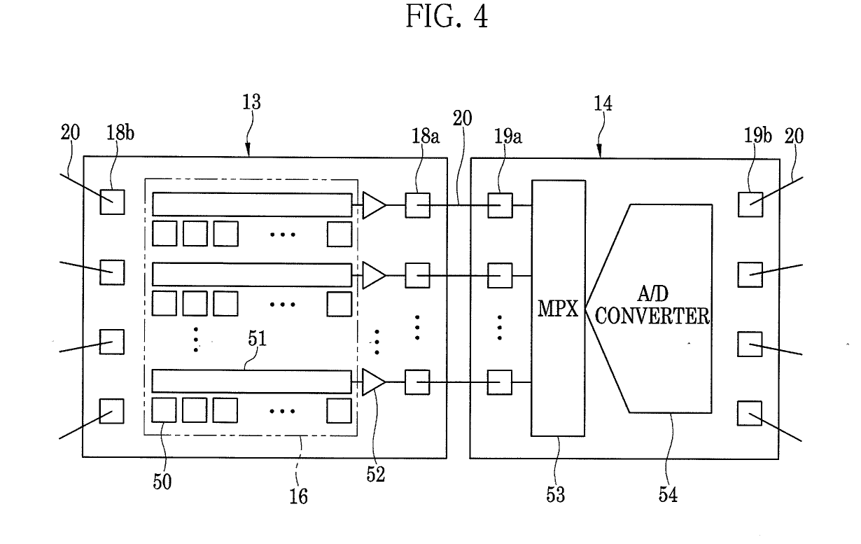

As shown in FIG. 4, the first semiconductor chip 13 is composed of a plurality of photoelectric-conversion elements 50, vertical transfer paths 51 and output amplifiers 52. The photoelectric-conversion elements 50 are arranged in a two-dimensional matrix within the light receiving area 16. The photoelectric-conversion element 50 photoelectrically converts incoming light into signal charges. The vertical transfer path 51 is provided alongside of each line of the photoelectric-conversion elements 50. The vertical transfer path 51 retrieves the signal charges from the photoelectric-conversion elements 50, and transfers the signal charges in a vertical direction (lateral direction of the drawing). The output amplifier 52 is provided at the end of each vertical transfer path 51. The output amplifier 52 converts the signal charges from the vertical transfer path 51 into voltage signals (image signal). The output amplifier 52 is composed of, for example, a floating diffusion amplifier (FD amp), whose output terminal to send out the image signals is connected to the electrode pad 18a. The image signals are entered from the electrode pads 18a to the electrode pads 19a through the wires 20.

The second semiconductor chip 14 is composed of a multiplexer 53 and an A/D converter 54. The image signals from the first semiconductor chip 13 are entered, in parallel, into the multiplexer 53 through the electrode pads 19a. The multiplexer 53 selects between the electrode pads 19a and enters the incoming image signals, sequentially, into the A/D converter 54 in accordance with a selection signal. The A/D converter 54 converts the image signal selected by the multiplexer 53 into a digital signal, and transmits the digital signal from the electrode pads 19b to the lead terminals 11.

As discussed above, the first semiconductor chip 13 does not have a horizontal transfer path, but is rather configured to output the image signals in parallel from the output amplifiers 52 that are connected to the vertical transfer paths 51. All the output amplifiers 52 and their connection wires are made to the same length, and theoretically there occurs no variation in potential difference (such as shading) between the image signals out of the electrode pads 18a. In addition, since each pair of the electrode pads 18a, 19a are arranged in parallel at a regular interval, and connected by the wire 20 of the same length, there occurs no variation in timing difference (such as skew) theoretically between the image signals to be entered into the multiplexer 53. Therefore, low-noise and high-quality images can be produced.

Next, with reference to FIG. 5, the manufacturing method of the semiconductor device 10 is described. In a first wafer processing step, a plurality of circuits for the first semiconductor chips 13 are formed in a silicon wafer using common semiconductor processing techniques. In a subsequent dicing step, the silicon wafer is cut into separate semiconductor chips 13 by a dicer.

In a second wafer processing step, a plurality of circuits for the second semiconductor chips 14 are formed in a silicon wafer using common semiconductor processing techniques. Since the circuit of the second semiconductor chip 14 is an A/D conversion circuit composed of a CMOS circuitry, a p-type substrate is used as the silicon wafer. Additionally, in this second wafer processing step, the Au bump 44 is formed by plating on each electrode pad 19a (on an exposed surface of the Al film 42). In a subsequent dicing step, the silicon wafer is cut into separate semiconductor chips 14 by a dicer.

In a die bonding step, the first and second semiconductor chips 13, 14 are arranged side by side, and fixed on the package base 12 by the adhesive layers 17. More specifically, as shown in FIG. 4, the semiconductor chips 13, 14 are arranged such that the output side of the first semiconductor chip 13 faces the input side of the second semiconductor chip 14.

Subsequently, the electrode pads 18b, 19b and the lead terminals 11 are interconnected through the wires 20 by wire bonding. Also, the electrode pads 18a, 19a of each pair are interconnected through the wires 20 by wire bonding. Then, in a glass sealing step, the cover glass 15 is adhered by the adhesive layer 21 so as to seal the opening of the package base 12, and thereby the first and second semiconductor chips 13, 14 are encapsulated air-tightly. The semiconductor device 10 is thus completed.

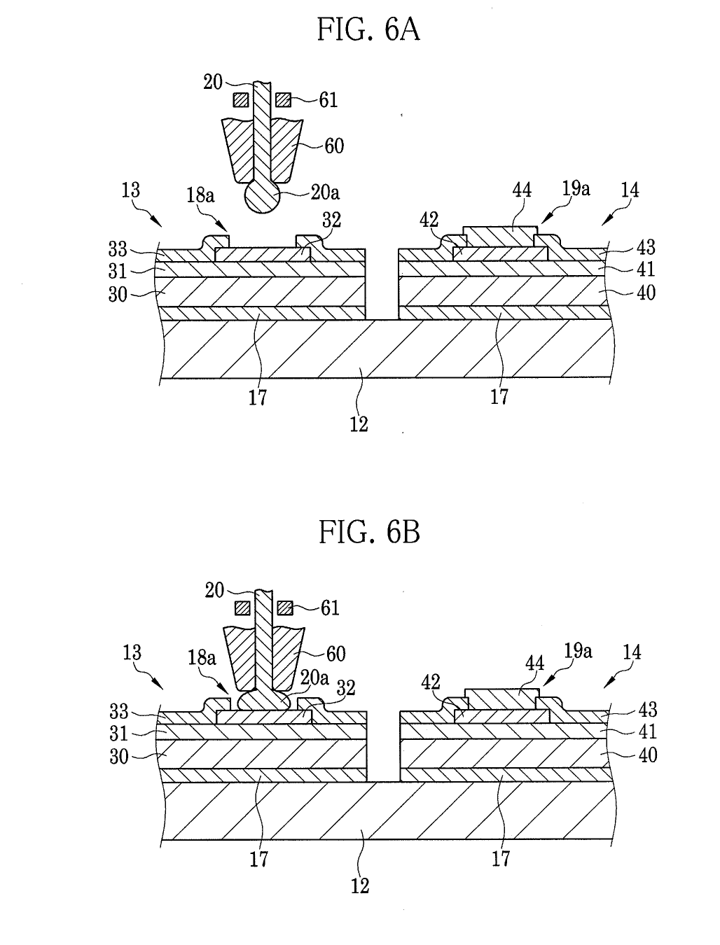

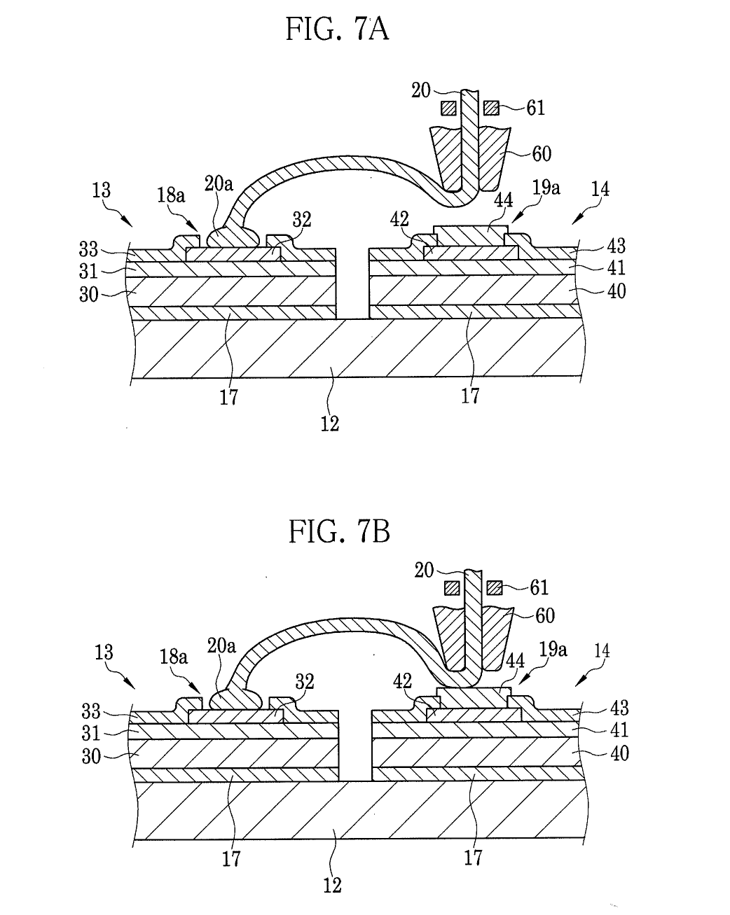

Next, with reference to FIG. 6 and FIG. 7, the wire bonding method to interconnect the electrode pads 18a, 19a of each pair is described. Firstly, one end of the wire 20 is joined to the electrode pad 18a by ball bonding.

More specifically, as shown in FIG. 6A, the wire 20 is inserted through a capillary 60 until it projects from the capillary 60. The ball 20a is formed, by spark discharge, at this projecting tip of the wire 20. Then, as shown in FIG. 6B, the ball 20a is pressed with the capillary 60 onto the electrode pad 18a (exposed surface of the Al film 32), and joined to the Al film 32 by ultrasonic welding. In this instance, Au—Al alloy is created at the point of contact of the ball 20a and the Al film 32.

Subsequently, as shown in FIG. 7A, the wire 20 is pulled out to above the electrode pad 19a as the capillary 60 moves in the horizontal direction, and joined to the Au bump 44 on the electrode pad 19a by stitch bonding.

More specifically, as shown in FIG. 7B, the capillary 60 is descended to the surface of the Au bump 44, and the wire 20 is joined to the Au bump 44 by ultrasonic welding. In this instance, a part of the wire 20 is compressed by the tip of the capillary 60. Subsequently, the wire 20 in the capillary 60 is held by a clamper 61, and the capillary 60 is ascended. The wire 20 is thereby severed at the compressed portion whose mechanical strength is lowered by the press of the capillary 60.

In this manner, the wire bonding to a pair of the electrode pads 18a, 19a is completed. Since the wire 20 and the Au bump 44 to be joined by stitch bonding are made of the same metallic material (Au—Au), adequate bond strength can be obtained by the pressing force of the capillary 60.

The electrode pads 18b and the lead terminals 11, and the electrode pads 19b and the lead terminals 11 are interconnected by wire bonding in the same manner as above. Namely, the ball 20a of the wire 20 is first joined to the electrode pad 18b or 19b by wire bonding, and the other end of the wire 20 is joined to the lead terminal 11 by stitch bonding. Since the lead terminal 11 is plated with gold, adequate bond strength is obtained.

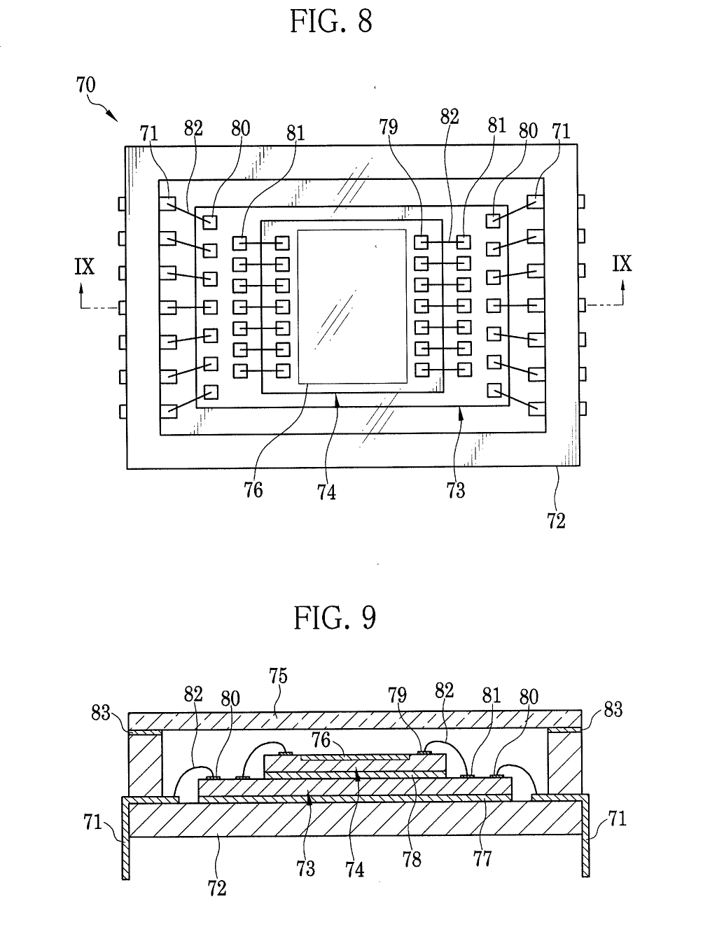

Next, the second embodiment of the present invention is described. In FIG. 8 and FIG. 9, a semiconductor device 70 includes a package base 72 having a plurality of lead terminals 71, a second semiconductor chip 73 fixed on the package base 72, a first semiconductor chip 74 fixed on the second semiconductor chip 73, and a transparent plate such as a cover glass 75 to cover an opening in an upper portion of the package base 72. The second semiconductor chip 73 is at least longer in one direction (horizontal direction of the drawing) than the first semiconductor chip 74.

Similarly to the first embodiment, the package base 72 is an open-topped, box-shaped container. Each lead terminal 71 penetrates side walls, and is folded in an L-shape. These lead terminals 71 are plated with gold.

The first semiconductor chip 74 is a CCD (Charge Coupled Device) type solid-state image sensor having a light receiving area 76 on the top surface. The second semiconductor chip 73 is a peripheral circuit element including an A/D conversion circuit for converting analog image signals from the first semiconductor chip 74 into digital signals, and a drive circuit for driving the first semiconductor chip 74. The second semiconductor chip 73 is fixed on the surface of the package base 72 by an adhesive layer 77, while the first semiconductor chip 74 is fixed on the surface of the second semiconductor chip 73 by an adhesive layer 78.

The first semiconductor chip 74 has two electrode pad arrays composed of electrode pads 79 arranged along two opposite sides of the chip. The second semiconductor chip 73 has two electrode pad arrays composed of electrode pads 80 arranged along the two opposite sides of the chip, and also has additional two electrode pad arrays composed of electrode pads 81 disposed inside of the arrays of the electrode pads 80.

The electrode pads 79 of the first semiconductor chip 74 are output terminals to send out image signals or input terminals to receive power supply voltages and drive signals. Each of the electrode pads 79 is connected through a wire 82 to one of the electrode pads 81 of the second semiconductor chip 73. The electrode pads 79, 81 are arranged at the same regular intervals (not more than 100 μm), such that each electrode pad 79 pairs with a corresponding one of the electrode pads 81. Additionally, the electrode pads 79, 81 of each pair are equally spaced, and the wires 82 connecting the pads have substantially the same length.

The electrode pads 80 of the second semiconductor chip 73 are output terminals to send out digital image signals or input terminals to receive power supply voltages and drive signals. Each of the electrode pads 80 is connected to one of the lead terminal 71 through the wire 82. The interval between the lead terminals 71 is 300 μm larger than the interval between the electrode pads 79, 80 or 81.

The cover glass 75 is fixed by an adhesive layer 83 provided on the top surfaces of the side walls of the package base 72. Together with the package base 72, the cover glass 75 air-tightly encapsulates the first and second semiconductor chips 74, 73 that are stacked above and below.

The first and second semiconductor chips 74, 73 have the same circuit configuration as the semiconductor chips in the first embodiment, and therefore detailed explanation thereof is omitted. A thing to note is that, although the electrode pads 79 of the first semiconductor chip 74 are not directly connected to the lead terminals 71, some of the electrode pads 80 of the second semiconductor chip 73 are connected to the electrode pads 79, though not shown, as well as the lead terminals 71. These electrode pads 80 enter power supply voltages and drive signals from outside to the first semiconductor chip 74.

The electrode pads 79, 80 have the same structure as the above electrode pads 18a, 18b in which the Al film is exposed from the surface protection film. Also, the electrode pads 81 have the same structure as the electrode pads 19a in the first embodiment.

The wire 82 is a thin gold (Au) line. One end of the wire 82 is connected to the electrode pad 79 by ball bonding, and the other end of the wire 82 is connected to the electrode pad 81 by stitch bonding. The bonding methods are identical to the first embodiment where adequate bond strength is obtained not only by ball bonding but also by stitch bonding.

The manufacturing method of the semiconductor device 70 thus configured is identical to the first embodiment, except that the first and second semiconductor chips 74, 73 are stacked above and below. Detailed explanation thereof is therefore omitted. In this semiconductor device 70, the electrode pads of the first and second semiconductor chips 74, 73 are also arranged in parallel and equally spaced to each other. Therefore, there occurs no variation in potential difference nor timing difference between the image signals, and low-noise and high-quality images can be produced.

Although the Au bumps in the above embodiments are formed by plating on the electrode pads before the second semiconductor chips are cut from the silicon wafer, the Au bumps may be formed using a bonding machine after the second semiconductor chips are cut from the wafer.

In the above embodiments, the first targets for the ball bonding are the electrode pads of the first semiconductor chip (solid-state image sensor), and the second targets for the stitch bonding are the electrode pads of the second semiconductor chip (peripheral circuit element). It may, however, be possible to invert the first and second targets, so that the ball bonding is performed to the electrode pads of the second semiconductor chip and the stitch bonding is performed to the electrode pads of the first semiconductor chip.

Although the above embodiments are described with using a solid-state image sensor and a peripheral circuit element as the first and second semiconductor chips, the present invention is applicable to various combinations of semiconductor chips, such as a memory circuit and a logic circuit.

In the above embodiments, the package base is sealed with the cover glass because the first semiconductor chip is the solid-state image sensor. However, in the event that the solid-state image sensor is not used, the package base may be sealed directly with transparent or opaque resin. Additionally, the number of the semiconductor chips to be encapsulated is not limited to two, but may be three or more.

Although the present invention has been fully described by the way of the preferred embodiments thereof with reference to the accompanying drawings, various changes and modifications will be apparent to those having skill in this field. Therefore, unless otherwise these changes and modifications depart from the scope of the present invention, they should be construed as included therein.

What is claimed is:

1. A wire bonding method comprising steps of:
arranging first and second semiconductor chips such that an array of first electrode pads of said first semiconductor chip lies next to an array of second electrode pads of said second semiconductor chip, each second electrode pad of said second electrode pad array having a gold bump formed thereon;
bonding one end of a gold wire to one of said first electrode pads by ball bonding; and
bonding the other end of said gold wire to said gold bump on one of said second electrode pads corresponding to said one first electrode pad by stitch bonding.

2. The wire bonding method of claim 1, wherein said gold wire is bonded in the middle to said gold bump and severed to form said the other end of said gold wire.

3. The wire bonding method of claim 2, wherein said first and second semiconductor chips are arranged side by side or stacked above and below, and fixed on a package base.

4. The wire bonding method of claim 3, wherein said first and second electrode pad arrays are parallel to each other.

5. A semiconductor device having first and second semiconductor chips arranged side by side or stacked above and below on a package base, comprising:
a first electrode pad array on said first semiconductor chip, said first electrode pad array having a plurality of first electrode pads arranged at regular intervals;
a second electrode pad array on said second semiconductor chip, said second electrode pad array having a plurality of second electrode pads arranged at regular intervals to correspond to said first electrode pad array, said first and second electrode pad arrays being parallel to each other;
a gold bump formed on each of said second electrode pads; and
a gold wire for interconnecting one of said first electrode pads to a corresponding one of said second electrode pads, one end of said gold wire being bonded to said first electrode pad by ball bonding, and the other end of said gold wire being bonded to said gold bump on said second electrode pad by stitch bonding.

6. The semiconductor device of claim 5, wherein said first semiconductor chip is a solid-state image sensor having photoelectric-conversion elements in a two-dimensional matrix arrangement, a vertical transfer path provided alongside of each line of said photoelectric-conversion elements, and an output amplifier provided at a terminal of each said vertical transfer path so as to convert signal charges from said vertical transfer path into voltage signals, and wherein each said output amplifier is connected to a corresponding one of said first electrode pads.

7. The semiconductor device of claim 6, wherein said second semiconductor chip includes a selector for selecting one of said second electrode pads, and an A/D converter for converting said voltage signal from said second electrode pad selected by said selector into a digital signal.

8. The semiconductor device of claim 7, wherein said package base has an open topped box shape, and a transparent plate is fixed onto said package base.
